(19) United States
(12) Patent Application Publication
(10) Pub. No.: US 2024/0360267 A1
(43) Pub. Date: Oct. 31, 2024

(54) RESIN COMPOSITION FOR FORMING ETCHING MASK PATTERN, AND METHOD FOR MANUFACTURING ETCHING MASK PATTERN

(71) Applicants: TOKYO OHKA KOGYO CO., LTD., Kawasaki-shi (JP); TOKYO INSTITUTE OF TECHNOLOGY, Tokyo (JP)

(72) Inventors: Takehiro SESHIMO, Kawasaki-shi (JP); Takahiro DAZAI, Kawasaki-shi (JP); Teruaki HAYAKAWA, Tokyo (JP); Shinsuke MAEKAWA, Tokyo (JP); Ryota UEHARA, Tokyo (JP)

(21) Appl. No.: 18/636,069

(22) Filed: Apr. 15, 2024

(30) Foreign Application Priority Data
Apr. 27, 2023 (JP) 2023-073814

(51) Int. Cl. C08F 297/02

(52) U.S. Cl. CPC C08F 297/026

(57) ABSTRACT

A resin composition for forming an etching mask pattern, with which a phase-separated structure having a period (L0) of less than 20 nm and having excellent vertical orientation even when subjected to high-temperature annealing can be obtained; and a method for manufacturing an etching mask pattern. The method includes applying the resin composition onto a support to form a block copolymer layer having a film thickness of 25 nm or more and phase-separating the block copolymer layer. The resin composition contains a block copolymer having a first block and a second block, the first block includes a structure of General Formula (b1), and the second block consists of a block 2M of a structure of General Formula (b2m) and a block 2G of a structure of General Formula (b2g), and y/(y+z) is 0.01 or more and 0.11 or less; R¹ is an alkyl group, R² is an alkyl group; and R³ is an alkylene group

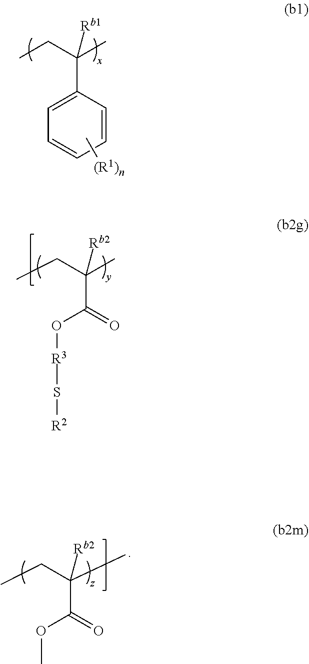

### BACKGROUND OF THE INVENTION

### Field of the Invention

The present invention relates to a resin composition for forming an etching mask pattern and a method for manufacturing an etching mask pattern.

Priority is claimed on Japanese Patent Application No. 2023-073814, filed on Apr. 27, 2023 and the content of which is incorporated herein by reference.

### Description of Related Art

In recent years, along with further miniaturization of large-scale integrated circuits (LSI), a technology for processing finer structure bodies has been demanded.

In response to such a demand, there has been developed a technology for forming a finer pattern by utilizing a phase-separated structure formed by self-organization of a block copolymer in which blocks incompatible with each other are bonded together (for example, see Japanese Unexamined Patent Application, First Publication No. 2008-36491).

In order to utilize the phase-separated structure of the block copolymer, it is considered essential to form self-organized nanostructures, which are formed by micro-phase separation, only in a specific region and arrange the nanostructures in a desired direction. In order to realize the position control and orientation control of these nanostructures, processes such as graphoepitaxy for controlling the phase-separated pattern by a guide pattern, and chemical epitaxy for controlling the phase-separated pattern by the difference in the chemical state of the substrate, have been proposed (for example, see Proceedings of SPIE, Vol. 7637, No. 76370G-1 (2010)).

The block copolymer forms a structure body having a regular periodic structure by the phase separation.

The phrase “period of a structure body” means the period of the phase structure observed when the structure body of a phase-separated structure is formed and refers to the sum of the lengths of the phases each of which is incompatible. In a case where the phase-separated structure forms a cylinder structure perpendicular to a surface of the substrate, the period (L0) of the structure body is a distance (pitch) between centers of two adjacent cylinder structures.

It is known that the period (L0) of the structure body is determined by inherent polymerization properties such as the degree of polymerization N and interaction parameter χ of Flory-Huggins. That is, as the product “χ×N” of χ and N is larger, the mutual repulsion between the different blocks in the block copolymer is greater. Therefore, in a case of the relation of χ×N>10.5 (hereinafter, referred to as “strong separation limit”), the repulsion between the different kinds of blocks in the block copolymer is large, and the tendency for phase separation to occur is strong. Accordingly, in the strong separation limit, the period of the structure body is approximately N^{2/3}×χ^{1/6}, and satisfies the relationship of the following expression (1). That is, the period of the structure body is proportional to the degree of polymerization N, which correlates with the molecular weight and the molecular weight ratio between the different blocks.

$$L 0 ∝ a \times {N}^{2 / 3} \times {χ}^{1 / 6} \qquad ( 1 )$$

in the expression, L0 represents a period of the structure body, a is a parameter indicating the size of the monomer, N represents a degree of polymerization, and χ is an interaction parameter, in which the value thereof is higher, the phase separation performance is higher]

Accordingly, the period (L0) of the structure body can be controlled by adjusting the composition and the total molecular weight of the block copolymer.

It has been known that the periodic structure formed by the block copolymer varies the form such as a cylinder (columnar phase), a lamella (plate phase), and a sphere (spherical phase) depending on a ratio of a volume of the polymer components, and the period depends on the molecular weight. Therefore, a method for increasing the molecular weight of the block copolymer has been considered in order to form a structure body of a relatively large period (L0) by utilizing the phase-separated structure formed by the self-organization of the block copolymer.

In addition, it has been also conceivable to use a method for using a block copolymer having a larger interaction parameter (c) than that of a block copolymer having a block of styrene and a block of methyl methacrylate, which is a general-purpose block copolymer. For example, Japanese Unexamined Patent Application, First Publication No. 2022-020519 proposes a block copolymer in which a substituent is introduced into a part of a methyl methacrylate block.

### SUMMARY OF THE INVENTION

### Problems to be Solved by Invention

The phase-separated structure formed by the self-organization of the block copolymer can be used for forming an etching mask pattern. In this case, it is preferable that the phase-separated structure is vertically oriented at a relatively thick film thickness (for example, a film thickness of 25 nm or more).

In order to form a phase-separated structure having a finer pattern, it is preferable that the period (L0) of the phase-separated structure is smaller and the phase-separated structure has vertical orientation. However, in the block copolymer disclosed in Japanese Unexamined Patent Application, First Publication No. 2022-020519, in a case where the period (L0) is small (for example, less than 20 nm), it is difficult to form the phase-separated structure having vertical orientation.

In addition, in order to obtain a highly accurate structure body, it is necessary to suppress occurrence of defects (surface defects). The term “defects” refers to general abnormalities of a phase-separated pattern, which are detected in a case of being observed from right above the phase-separated pattern, using a scanning electron microscope or the like. As these abnormalities, for example, abnormalities caused by the deposition of foreign substances and deposits on a surface of the phase-separated pattern, such as scum (resin composition residues) after the formation of the phase-separated pattern, foam, and dust, abnormalities with regard to pattern shapes, such as bridges across different portions of the line pattern and the filling of holes in contact hole patterns, and color irregularities in the pattern are included.

The above-described phase-separated structure can be obtained by annealing a block copolymer applied onto a substrate or the like. In general, in order to suppress the occurrence of defects in the phase-separated pattern, it is preferable to set the temperature of the annealing to be high. However, in the block copolymer disclosed in Japanese Unexamined Patent Application, First Publication No. 2022-020519, in a case where the annealing temperature is high (for example, 290° C.), it is difficult to form a phase-separated structure having vertical orientation.

The present invention has been made in consideration of the above circumstances, and an object of the present invention is to provide a resin composition for forming an etching mask pattern, with which a phase-separated structure having a period (L0) of less than 20 nm and having excellent vertical orientation even in a case of being subjected to high-temperature annealing can be obtained, and a method for manufacturing an etching mask pattern using the same.

### Means for Solving Problems

A first aspect of the present invention is a method for manufacturing an etching mask pattern, including a step of applying a resin composition for forming an etching mask pattern onto a support to form a layer containing a block copolymer and having a film thickness of 25 nm or more, and a step of phase-separating the layer containing the block copolymer, in which the resin composition for forming an etching mask pattern contains a block copolymer having a first block and a second block, the first block is composed of a polymer consisting of a repeating structure of a constitutional unit represented by General Formula (b1), and the second block consists of a block 2M which is composed of a polymer consisting of a repeating structure of a constitutional unit represented by General Formula (b2m) and a block 2G which is composed of a polymer consisting of a repeating structure of a constitutional unit represented by General Formula (b2g).

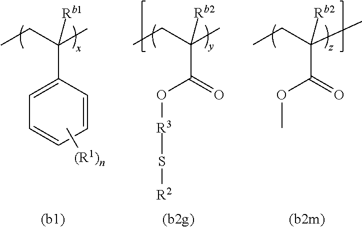

in Formula (b1), R¹ is an alkyl group which may have an oxygen atom or a silicon atom, n is an integer of 0 to 5, and R^{b1} is a hydrogen atom or a methyl group,
in Formula (b2g), R² is an alkyl group which may have a silicon atom, a fluorine atom, a carboxy group, an amino group, a cyano group, a hydroxy group, or a phosphoric acid group, and
R³ is a linear alkylene group having 1 to 10 carbon atoms or a branched alkylene group having 2 to 10 carbon atoms, each of which may have a hydroxy group,
in Formulae (b2g) and (b2m), R^{b2}'s are each independently a hydrogen atom, an alkyl group having 1 to 5 carbon atoms, or a halogenated alkyl group having 1 to 5 carbon atoms,
x, y, and z represent a molar ratio, x+y+z is 100 mol %, y/(y+z) is 0.01 or more and 0.11 or less, and x is 20 to 80 mol %]

A second aspect of the present invention is a resin composition for forming an etching mask pattern, containing a block copolymer having a first block and a second block, in which the first block is composed of a polymer consisting of a repeating structure of a constitutional unit represented by General Formula (b1), and the second block consists of a block 2M which is composed of a polymer consisting of a repeating structure of a constitutional unit represented by General Formula (b2m) and a block 2G which is composed of a polymer consisting of a repeating structure of a constitutional unit represented by General Formula (b2g).

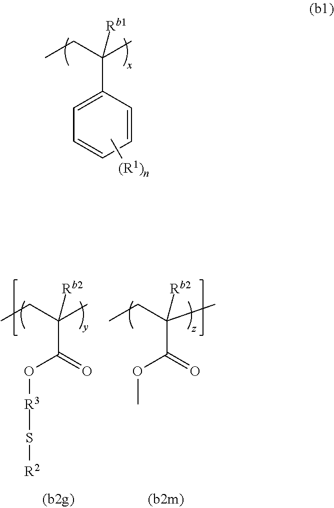

in Formula (b1), R¹ is an alkyl group which may have an oxygen atom or a silicon atom, n is an integer of 0 to 5, and R^{b1} is a hydrogen atom or a methyl group, in Formula (b2g), R² is an alkyl group which may have a silicon atom, a fluorine atom, a carboxy group, an amino group, a cyano group, a hydroxy group, or a phosphoric acid group, and R³ is a linear alkylene group having 1 to 10 carbon atoms or a branched alkylene group having 2 to 10 carbon atoms, each of which may have a hydroxy group, in Formulae (b2g) and (b2m), R^{b2}'s are each independently a hydrogen atom, an alkyl group having 1 to 5 carbon atoms, or a halogenated alkyl group having 1 to 5 carbon atoms, x, y, and z represent a molar ratio, x+y+z is 100 mol %, y/(y+z) is 0.01 or more and 0.11 or less, and x is 20 to 80 mol %

### Effect of Invention

According to the present invention, it is possible to provide a resin composition for forming an etching mask pattern, which has excellent vertical orientation with a high film thickness, and a method for manufacturing an etching mask pattern using the same.

### BRIEF DESCRIPTION OF THE DRAWINGS

FIG. 1 is a schematic process diagram for explaining an exemplary embodiment of a method for manufacturing an etching mask pattern.

FIG. 2 is a diagram for explaining an exemplary embodiment of an optional step.

### DETAILED DESCRIPTION OF THE INVENTION

In the present specification and the scope of the present claims, the term “aliphatic” is a relative concept used with respect to “aromatic” and defines a group or compound that has no aromaticity.

A term “alkyl group” includes linear, branched, or cyclic monovalent saturated hydrocarbon groups unless otherwise specified. The same applies to an alkyl group in an alkoxy group.

A term “alkylene group” includes linear, branched, or cyclic divalent saturated hydrocarbon groups unless otherwise specified.

A “halogenated alkyl group” is a group in which a part of or all of hydrogen atoms in an alkyl group are substituted with halogen atoms. As the halogen atom, a fluorine atom, a chlorine atom, a bromine atom, and an iodine atom are exemplary examples.

The “fluorinated alkyl group” or a “fluorinated alkylene group” is a group obtained by substituting part or all of hydrogen atoms of an alkyl group or an alkylene group with a fluorine atom.

A term “constitutional unit” indicates a monomer unit constituting a polymer compound (a resin, a polymer, or a copolymer).

An expression “may have a substituent” includes a case where a hydrogen atom (—H) is substituted with a monovalent group and a case where a methylene group (—CH₂—) is substituted with a divalent group.

A term “exposure” is used as a general concept for irradiation with radiation.

A term “α-position (carbon atom at α-position)” means a carbon atom to which a side chain of a block copolymer is bonded, unless otherwise specified. The “carbon atom at the α-position” of a methyl methacrylate unit means a carbon atom to which a carbonyl group of methacrylic acid is bonded. The “carbon atom at the α-position” of a styrene unit means a carbon atom to which a benzene ring is bonded.

A term “number-average molecular weight” (Mn) is a number-average molecular weight in terms of standard polystyrene measured by size-exclusion chromatography, unless otherwise specified. A term “mass-average molecular weight” (Mw) is a mass-average molecular weight in terms of standard polystyrene measured by size-exclusion chromatography, unless otherwise specified. A value obtained by adding a unit (g·mol⁻) to the value of Mn or Mw represents a molar mass.

In the detailed description and claims of the present invention, in the specification and claims of the present invention, some structures represented by a chemical formula have an asymmetric carbon, and there may be enantiomers and diastereomers. Those isomers are collectively represented by one formula. These isomers may be used alone or in the form of a mixture.

### Method for Manufacturing Etching Mask Pattern

The method for manufacturing an etching mask pattern according to the present embodiment includes a step of applying the resin composition for forming an etching mask pattern according to the above-described embodiment onto a support to form a layer containing a block copolymer (hereinafter, referred to as “step (i)”); a step of phase-separating the layer containing a block copolymer (hereinafter, referred to as “step (ii)”); and a step of selectively removing a phase consisting of at least one block of a first block or a second block constituting the component (BCP) in a BCP layer 3 (hereinafter, referred to as “step (iii)”).

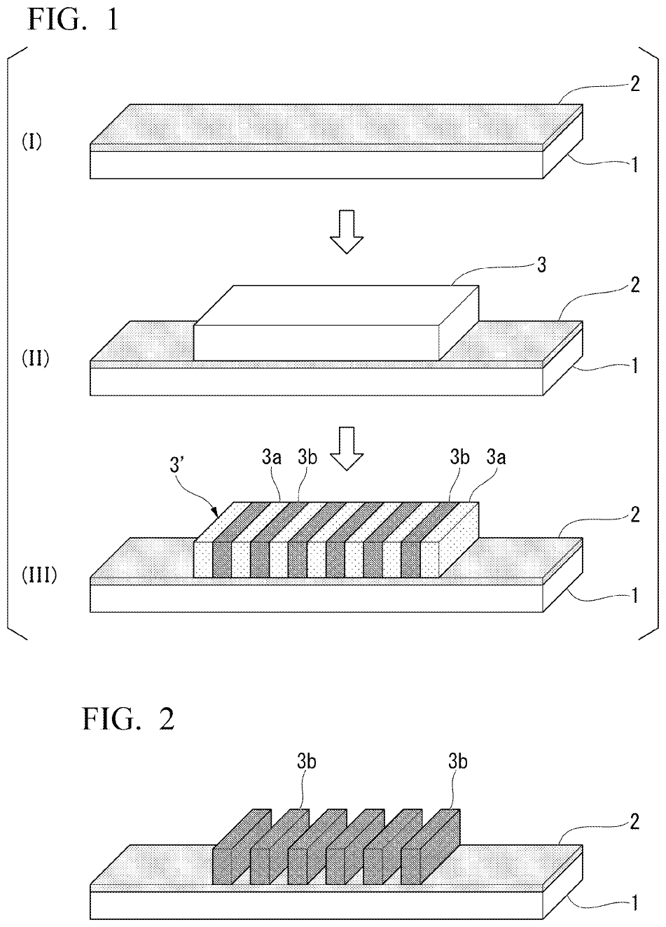

Hereinafter, the method for manufacturing an etching mask pattern will be specifically described with reference to FIG. 1. However, the present invention is not limited thereto.

FIG. 1 shows an exemplary embodiment of the method for manufacturing an etching mask pattern.

In the embodiment shown in FIG. 1, first, an undercoat agent layer 2 is formed by applying an undercoat agent onto a support 1 (FIG. 1(I)).

Next, the above-described resin composition for forming an etching mask pattern according to the embodiment is applied onto the undercoat agent layer 2 to form a layer (BCP layer) 3 containing a block copolymer (FIG. 1(II); above, step (i)).

Next, the BCP layer 3 is phase-separated into a phase 3a and a phase 3b by a heating and annealing treatment (FIG. 1(III); step (ii)).

As a result, a structure body 3′ including a phase-separated structure is produced on the support 1 on which the undercoat agent layer 2 had been formed. The structure body 3′ including the phase-separated structure can be for manufacturing an etching mask pattern.

The “first block” and “second block” in the resin composition for forming an etching mask pattern, which will be described later, may be referred to as “block (b1)” and “block (b2)”.

### Step (i)

In the step (i), the support 1 is coated with the resin composition for forming an etching mask pattern to form the BCP layer 3 having a film thickness of 25 nm or more.

In the embodiment shown in FIG. 1, first, the undercoat agent layer 2 is formed by applying the undercoat agent onto the support 1.

By providing the undercoat agent layer 2 on the support 1, a hydrophilic and hydrophobic balance between a surface of the support 1 and the layer 3 containing the block copolymer (BCP layer) can be achieved.

That is, in a case where the undercoat agent layer 2 contains a resin component having the constitutional unit constituting the above-described block (b1), adhesiveness between the phase of the BCP layer 3, formed of the block (b1), and the support 1 is enhanced. In a case where the undercoat agent layer 2 contains a resin component having the constitutional unit constituting the above-described block (b2), adhesiveness between the phase of the BCP layer 3, formed of the block (b2), and the support 1 is enhanced.

Accordingly, a cylinder structure or a lamellar structure, oriented in a direction perpendicular to the surface of the support 1, is likely to be formed due to the phase separation of the BCP layer 3.

### Step (ii)

In the step (ii), the BCP layer 3 formed on the support 1 is phase-separated.

By heating the support 1 after the step (i) to perform an annealing treatment, a phase-separated structure is formed such that at least a portion of the surface of the support 1 is exposed by selective removal of the block copolymer. That is, the structure body 3′ including a phase-separated structure which is phase-separated into a phase 3a and a phase 3b is produced on the support 1.

The annealing treatment is preferably performed under a temperature condition of equal to or higher than a glass transition temperature of the component (BCP) used and lower than a thermal decomposition temperature thereof. For example, in a case where the block copolymer is a polystyrene-poly(methyl methacrylate) (PS-PMMA) block copolymer (mass-average molecular weight: 5,000 to 100,000), the temperature is preferably 250° C. to 300° C., more preferably 260° C. to 295° C., and particularly preferably 270° C. to 290° C. The heating time is preferably 30 to 3600 seconds.

In addition, it is preferable that the annealing treatment is performed in a gas having low reactivity, such as nitrogen.

Step (iii)

In the step (iii), a phase consisting of at least one block of the first block or the second block constituting the above-described component (BCP) is selectively removed from the structure body 3′. As a result, an etching mask pattern is formed.

As a method of selectively removing the phase including any of the blocks, a method of performing an oxygen plasma treatment on the BCP layer, a method of performing a hydrogen plasma treatment on the BCP layer, and the like are exemplary examples.

For example, after the BCP layer containing the above-described component (BCP) is phase-separated, the BCP layer is subjected to an oxygen plasma treatment, a hydrogen plasma treatment, or the like, so that the phase including the first block is not selectively removed, and the phase including the second block is selectively removed.

FIG. 2 shows an exemplary embodiment of the step (iii).

In the embodiment shown in FIG. 2, in a case where the phase 3a is selectively removed and an etching mask pattern from the separated phase 3b is formed by performing an oxygen plasma treatment on the structure body 3′ produced on the support 1 in the step (ii). In this case, the phase 3b is a phase formed of the first block, and the phase 3a is a phase formed of the second block.

The etching mask pattern obtained as described above can be used for etching the support as it is, but a shape of the etching mask pattern on the support 1 can be changed by further heating.

Regarding the temperature conditions for the heating, it is preferable that the annealing treatment is performed at a temperature equal to or higher than a glass transition temperature of the block copolymer used and lower than a thermal decomposition temperature. In addition, the heating is preferably performed in a gas having low reactivity, such as nitrogen.

In the method for manufacturing an etching mask pattern according to the present embodiment, by using a resin composition for forming an etching mask pattern as described below, a phase-separated structure having a period (L0) of less than 20 nm and having excellent vertical orientation can be obtained even in a case of being subjected to high-temperature annealing. Hereinafter, the resin composition for forming an etching mask pattern will be described in detail.

### Resin Composition for Forming Etching Mask Pattern

The resin composition for forming an etching mask pattern according to the present embodiment contains a block copolymer having a first block and a second block. The first block is composed of a polymer consisting of a repeating structure of a constitutional unit represented by General Formula (b1). The second block consists of a block 2M which is composed of a polymer consisting of a repeating structure of a constitutional unit represented by General Formula (b2m) and a block 2G which is composed of a polymer consisting of a repeating structure of a constitutional unit represented by General Formula (b2g).

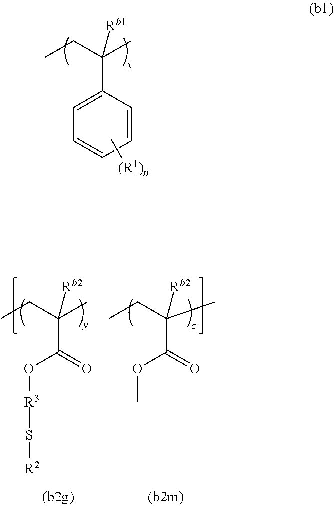

in Formula (b1), R¹ is an alkyl group which may have an oxygen atom or a silicon atom, n is an integer of 0 to 5, and R^{b1} is a hydrogen atom or a methyl group,
in Formula (b2g), R² is an alkyl group which may have a silicon atom, a fluorine atom, a carboxy group, an amino group, a cyano group, a hydroxy group, or a phosphoric acid group, and
R³ is a linear alkylene group having 1 to 10 carbon atoms or a branched alkylene group having 2 to 10 carbon atoms, each of which may have a hydroxy group,
in Formulae (b2g) and (b2m), R^{b2}'s are each independently a hydrogen atom, an alkyl group having 1 to 5 carbon atoms, or a halogenated alkyl group having 1 to 5 carbon atoms,
x, y, and z represent a molar ratio, x+y+z is 100 mol %, y/(y+z) is 0.01 or more and 0.11 or less, and x is 20 to 80 mol %]

### Block Copolymer: Component (BCP)

The block copolymer is a polymer in which a plurality of types of blocks (partial structural components in which constitutional units of the same type are repeatedly bonded) are bonded. The blocks constituting the block copolymer may be two types or may be three or more types.

The block copolymer (hereinafter, also referred to as “component (BCP)”) in the present embodiment has a first block and a second block.

### First Block

The first block is composed of a polymer consisting of a repeating structure of a constitutional unit represented by General Formula (b1) (hereinafter, also referred to as a constitutional unit (b1)).

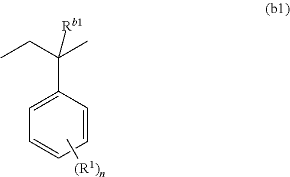

in the formula, R¹ is an alkyl group which may have an oxygen atom or a silicon atom, R^{b1} is a hydrogen atom or a methyl group, n is an integer of 0 to 5, and in a case where n is an integer of 2 or more, a plurality of R's may be the same or different from each other

In Formula (b1), R¹ is an alkyl group which may have an oxygen atom or a silicon atom. The number of carbon atoms in the above-described alkyl group is preferably 1 to 5, more preferably 1 to 4, and still more preferably 1 to 3, and the above-described alkyl group is even more preferably an ethyl group or a methyl group. R¹ is particularly preferably a methyl group.

In Formula (b1), R^{b1} is a hydrogen atom or a methyl group.

In Formula (b1), n is preferably 0 to 3, more preferably 0 to 2, and still more preferably 0 or 1.

### Second Block

The second block consists of a block 2M and a block 2G. The block 2M is composed of a polymer consisting of a repeating structure of a constitutional unit represented by General Formula (b2m) (hereinafter, also referred to as a constitutional unit (b2m)). The block 2G is composed of a polymer consisting of a repeating structure of a constitutional unit represented by General Formula (b2g) (hereinafter, also referred to as a constitutional unit (b2g)).

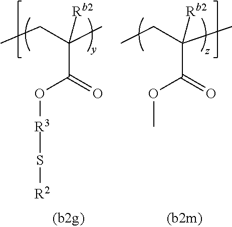

in Formula (b2g), R² is an alkyl group which may have a silicon atom, a fluorine atom, a carboxy group, an amino group, a cyano group, a hydroxy group, or a phosphoric acid group, and
R³ is a linear alkylene group having 1 to 10 carbon atoms or a branched alkylene group having 2 to 10 carbon atoms, each of which may have a hydroxy group,
in Formulae (b2g) and (b2m), R^{b2}'s are each independently a hydrogen atom, an alkyl group having 1 to 5 carbon atoms, or a halogenated alkyl group having 1 to 5 carbon atoms
   Constitutional Unit (b2m)

The constitutional unit (b2m) is a constitutional unit represented by General Formula (b2m).

In Formula (b2m), R^{b2} is a hydrogen atom, an alkyl group having 1 to 5 carbon atoms, or a halogenated alkyl group having 1 to 5 carbon atoms. As the alkyl group having 1 to 5 carbon atoms as R^{b2}, a linear or branched alkyl group having 1 to 5 carbon atoms is preferable, and specifically, a methyl group, an ethyl group, a propyl group, an isopropyl group, an n-butyl group, an isobutyl group, a tert-butyl group, a pentyl group, an isopentyl group, a neopentyl group, and the like are exemplary examples. The halogenated alkyl group having 1 to 5 carbon atoms is a group in which a part of or all hydrogen atoms in the alkyl group having 1 to 5 carbon atoms are substituted with halogen atoms. The halogen atom is particularly preferably a fluorine atom.

R^{b2} is preferably a hydrogen atom, an alkyl group having 1 to 5 carbon atoms, or a fluorinated alkyl group having 1 to 5 carbon atoms; and from the viewpoint of industrial availability, more preferably a hydrogen atom or a methyl group and still more preferably a methyl group.

Constitutional Unit (b2g)

The constitutional unit (b2g) is a constitutional unit represented by General Formula (b2g).

In Formula (b2g), R^{b2} is a hydrogen atom, an alkyl group having 1 to 5 carbon atoms, or a halogenated alkyl group having 1 to 5 carbon atoms. The R^{b2} is the same as R^{b2} in Formula (b2m) described above.

In Formula (b2g), R² is an alkyl group which may have a silicon atom, a fluorine atom, a carboxy group, an amino group, a cyano group, a hydroxy group, or a phosphoric acid group. The above-described alkyl group is preferably a linear or branched alkyl group, and more preferably a linear alkyl group. In a case where the above-described alkyl group is linear, it is sufficient that the number of carbon atoms therein is 1 or more, preferably 2 or more. The upper limit of the number of carbon atoms in the above-described linear alkyl group is not particularly limited, but from the viewpoint of phase separation performance, it is preferably 15 or less, more preferably 10 or less, still more preferably 8 or less, even more preferably 6 or less, and particularly preferably 5 or less. In a case where the above-described alkyl group is branched, it is sufficient that the number of carbon atoms therein is 3 or more. The upper limit of the number of carbon atoms in the above-described branched alkyl group is not particularly limited, but from the viewpoint of phase separation performance, it is preferably 15 or less, more preferably 10 or less, still more preferably 8 or less, even more preferably 6 or less, and particularly preferably 5 or less. The number of carbon atoms in the above-described alkyl group is preferably 2 to 15, more preferably 2 to 10, still more preferably 2 to 8, even more preferably 2 to 6, and particularly preferably 2 to 5.

The alkyl group of R² is preferably a linear alkyl group having 2 to 5 carbon atoms.

The alkyl group as R² may have a silicon atom, a fluorine atom, a carboxy group, an amino group, a cyano group, a hydroxy group, or a phosphoric acid group. In a case where the alkyl group as R² has a fluorine atom, a carboxy group, an amino group, a cyano group, a hydroxy group, or a phosphoric acid group, the fluorine atom, carboxy group, amino group, cyano group, hydroxy group, or phosphoric acid group may be a substituent which substitutes a hydrogen atom of the alkyl group. The number of hydrogen atoms substituted in the above-described group is not particularly limited, but is preferably 1 to 3.

In a case where the alkyl group of R² has a silicon atom, the silicon atom may be a substituent which substitutes a methylene group (—CH₂—) in the alkyl group. The number of methylene groups substituted with the silicon atom is not particularly limited, but is preferably 1.

R² is preferably an alkyl group which may be substituted with an alkylsilyl group, a fluoromethyl group, a carboxy group, an amino group, a cyano group, a hydroxy group, or a phosphoric acid group. The alkyl group in the above-described alkylsilyl group preferably has 1 to 3 carbon atoms and more preferably has 1 or 2 carbon atoms. The above-described alkylsilyl group is preferably a trialkylsilyl group, more preferably a triethylsilyl group or a trimethylsilyl group, and still more preferably a trimethylsilyl group. The above-described fluoromethyl group is preferably a trifluoromethyl group.

Preferred examples of R² are shown below, but it is not limited thereto. In the formulae, * is a bonding site bonding to a sulfur atom (S) in Formula (b2g).

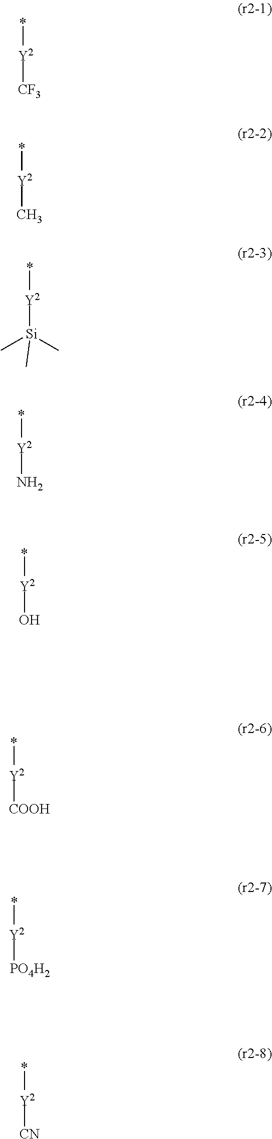

in the formulae, Y² is a linear or branched alkylene group having 1 to 15 carbon atoms

In Formulae (r2-1) to (r2-8), Y² is a linear or branched alkylene group having 1 to 15 carbon atoms. In a case where the above-described alkylene group is linear, the number of carbon atoms in the linear alkylene group is more preferably 1 to 10, still more preferably 1 to 8, and particularly preferably 1 to 5. In a case where the above-described alkylene group is branched, the number of carbon atoms in the branched alkylene group is more preferably 2 to 10, still more preferably 2 to 8, and particularly preferably 2 to 5.

The alkylene group as Y² is preferably a linear alkylene group having 1 to 5 carbon atoms.

Specific examples of R² are shown below, but it is not limited thereto. In the formulae, * is a bonding site bonding to a sulfur atom (S) in Formula (b2g).

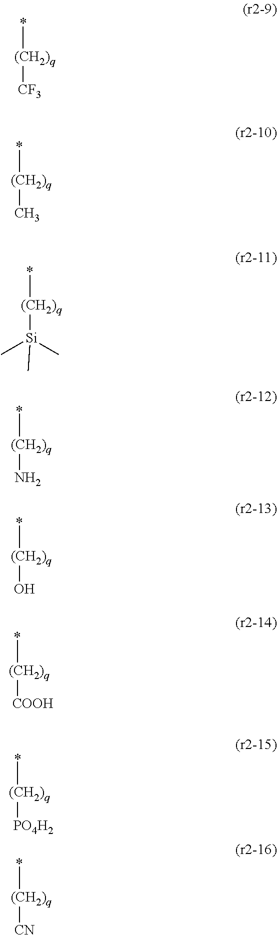

in the formulae, q is an integer of 1 to 15

In the formulae, q is preferably 1 to 10, more preferably 1 to 8, still more preferably 1 to 6, and particularly preferably 1 to 5.

In Formula (b2g), R³ is a linear or branched alkylene group having 1 to 10 carbon atoms, which may have a hydroxy group. In a case where the above-described alkylene group is linear, it is sufficient that the number of carbon atoms therein is 1 or more, preferably 3 or more. From the viewpoint of phase separation performance, the upper limit of the number of carbon atoms in the above-described linear alkylene group is preferably 8 or less, more preferably 5 or less, and still more preferably 4 or less. The number of carbon atoms in the above-described linear alkylene group is particularly preferably 3. In a case where the above-described alkylene group is branched, it is sufficient that the number of carbon atoms therein is 3 or more, preferably 4 or more. From the viewpoint of phase separation performance, the upper limit of the number of carbon atoms in the above-described branched alkylene group is preferably 8 or less, and more preferably 5 or less. The number of carbon atoms in the above-described alkyl group is preferably 3 to 10, more preferably 3 to 8, still more preferably 3 to 5, even more preferably 3 or 4, and particularly preferably 3.

The alkylene group as R³ is preferably a linear alkylene group having 3 carbon atoms.

The alkylene group as R³ may have a hydroxy group. The above-described hydroxy group may be a substituent which substitutes a hydrogen atom of the alkylene group. The number of hydrogen atoms substituted by the hydroxy group is not particularly limited, but is preferably 1 to 3, more preferably 1 or 2, and still more preferably 1.

The constitutional unit (b2g) is preferably a constitutional unit represented by General Formula (b2g-1).

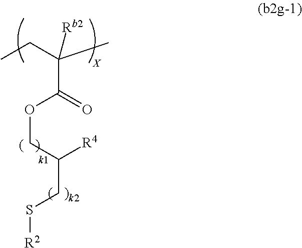

in the formula, R⁴ is a hydrogen atom or a hydroxy group, k¹ and k² are each independently an integer of 1 to 5, and R^{b2} and R² are the same as R^{b2} and R² in Formula (b2g) described above

In Formula (b2g-1), R^{b2} and R² are the same as R^{b2} and R² in Formula (b2g) described above. R² is preferably represented by Formulae (r2-1) to (r2-8) and more preferably represented by Formulae (r2-9) to (r2-16).

In Formula (b2g-1), R⁴ is a hydrogen atom or a hydroxy group.

In Formula (b2g-1), k¹ and k² are each independently an integer of 1 to 5. k¹ and k² are preferably 1 to 3, more preferably 1 or 2, and still more preferably 1.

Specific examples of the constitutional unit (b2g) are shown below, but it is not limited thereto. In the formulae, R represents a methyl group or a hydrogen atom, and a methyl group is preferable.

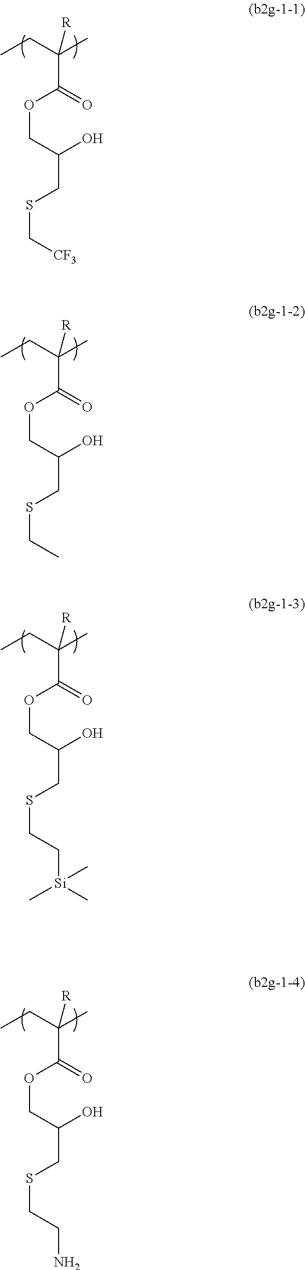

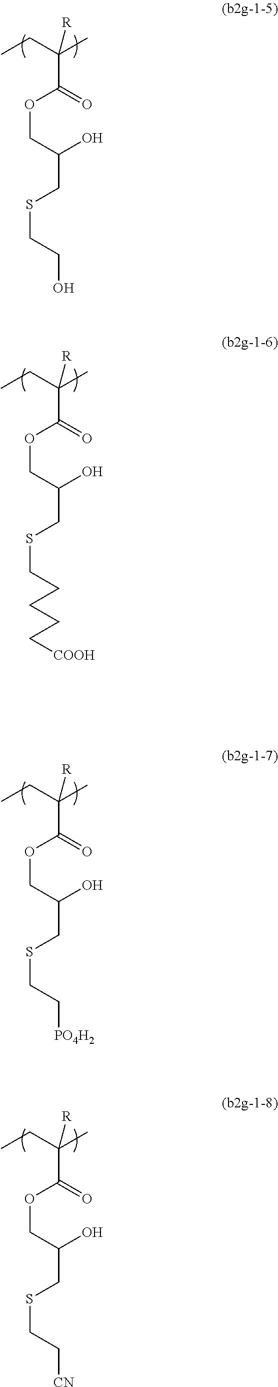

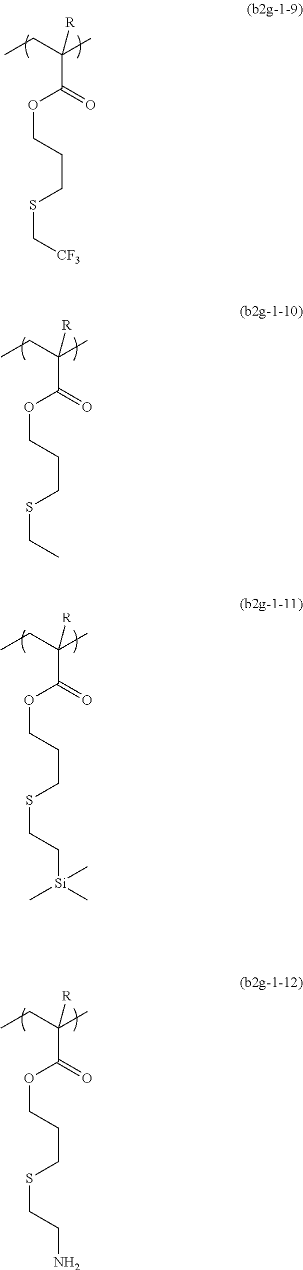

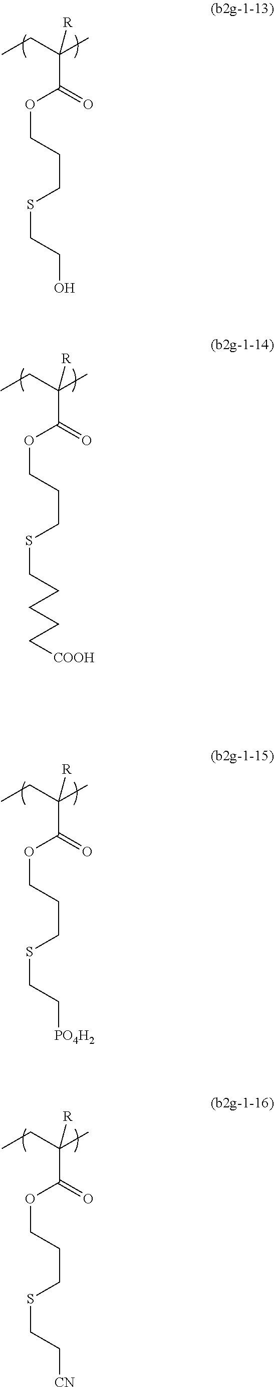

In Formulae (b1), (b2g), and (b2m), x, y, and z represent a molar ratio. x+y+z is 100 mol %. y/(y+z) is 0.01 or more and 0.11 or less.

x is preferably 20 to 80 mol %, more preferably 25 to 75 mol %, and still more preferably 30 to 70 mol %. In a case where x is within the above-described range, a phase-separated structure having a period (L0) of less than 20 nm and having excellent vertical orientation is easily obtained even in a case of being subjected to high-temperature annealing.

y is preferably 0.5 to 8 mol %, more preferably 1 to 7 mol %, and still more preferably 1.5 to 6 mol %. In a case where y is within the above-described range, a phase-separated structure having a period (L0) of less than 20 nm and having excellent vertical orientation is easily obtained even in a case of being subjected to high-temperature annealing.

z is preferably 10 to 70 mol %, more preferably 15 to 65 mol %, and still more preferably 20 to 60 mol %. In a case where z is within the above-described range, a phase-separated structure having a period (L0) of less than 20 nm and having excellent vertical orientation is easily obtained even in a case of being subjected to high-temperature annealing.

y/(y+z) is preferably 0.02 or more, more preferably 0.03 or more, still more preferably 0.04 or more, particularly preferably 0.05 or more, and most preferably 0.06 or more. y/(y+z) is preferably 0.109 or less, more preferably 0.105 or less, still more preferably 0.103 or less, and particularly preferably 0.100 or less.

In a case where y/(y+z) is within the above-described range, a phase-separated structure having a period (L0) of less than 20 nm and having excellent vertical orientation is easily obtained even in a case of being subjected to high-temperature annealing.

The component (BCP) may have other blocks in addition to the first block and the second block. As a preferred aspect, the component (BCP) is a block copolymer composed of the first block and the second block.

A number-average molecular weight (Mn) (in terms of polystyrene according to size-exclusion chromatography) of the component (BCP) is not particularly limited, but is preferably 5,000 to 100,000, more preferably 10,000 to 80,000, still more preferably 15,000 to 70,000, particularly preferably 15,000 to 50,000, and most preferably 20,000 to 35,000.

A polydispersity (Mw/Mn) of each block constituting the component (BCP) is preferably 1.0 to 1.5, more preferably 1.0 to 1.4, and still more preferably 1.0 to 1.3.

### Organic Solvent Component

The above-described resin composition for forming an etching mask pattern can be prepared by dissolving the above-described component (BCP) in an organic solvent component.

Any organic solvent component may be used as long as it can dissolve each component to be used and form a homogeneous solution, and arbitrary solvents may be selected from any solvents known in the related art as a solvent for a film composition containing a resin as a main component.

As the organic solvent component, for example, lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and the like are exemplary examples.

The organic solvent component may be used alone or as a mixed solvent of two or more kinds thereof. Among these, propylene glycol monomethyl ether acetate (PGMEA), propylene glycol monomethyl ether (PGME), cyclohexanone, or EL is preferable.

In addition, a mixed solvent obtained by mixing PGMEA with a polar solvent is also preferable. A blending ratio (mass ratio) of the mixed solvent can be appropriately determined in consideration of compatibility between PGMEA and the polar solvent, and it is preferably in a range of 1:9 to 9:1 and more preferably in a range of 2:8 to 8:2.

For example, in a case where EL is blended as the polar solvent, a mass ratio of PGMEA:EL is preferably 1:9 to 9:1 and more preferably 2:8 to 8:2. In addition, in a case where PGME is blended as the polar solvent, a mass ratio of PGMEA:PGME is preferably 1:9 to 9:1, more preferably 2:8 to 8:2, and still more preferably 3:7 to 7:3. In addition, in a case where PGME and cyclohexanone are blended as the polar solvent, a mass ratio of PGMEA:(PGME+cyclohexanone) is preferably 1:9 to 9:1, more preferably 2:8 to 8:2, and still more preferably 3:7 to 7:3.

In addition, as the organic solvent component in the resin composition for forming an etching mask pattern, in addition to those solvents, a mixed solvent in which PGMEA, EL, or the above-described mixed solvent of PGMEA and a polar solvent is mixed with γ-butyrolactone is also preferable. In this case, as a mixing proportion, a mass ratio of the former and the latter is preferably set to 70:30 to 95:5.

The concentration of the organic solvent component contained in the resin composition for forming an etching mask pattern is not particularly limited, and the component is appropriately set at a concentration with which the coating can be performed according to the coating film thickness. A concentration of solid contents is generally used in a range of 0.2% to 70% by mass, preferably in a range of 0.2% to 50% by mass.

### Optional Component

In addition to the above-described component (BCP) and organic solvent component, the above-described resin composition for forming an etching mask pattern may further contain, as desired, a miscible additive such as an additional resin for improving the performance of the layer, a surfactant for improving coatability, a dissolution inhibitor, a plasticizer, a stabilizer, a colorant, a halation inhibitor, a dye, a sensitizer, a base promoter, and a basic compound.

### Undercoat Agent:

As the undercoat agent, a resin composition containing a resin component can be used.

The resin component for the undercoat agent can be appropriately selected from the resin components known in the related art, which are used for forming a thin film depending on the type of the blocks constituting the component (BCP).

The resin component for the undercoat agent may be, for example, a thermopolymerizable resin or a photosensitive resin contained in a positive-tone resist composition, a negative-tone resist composition, or the like. In addition, a non-polymerizable film formed by applying a compound as a surface treating agent may be used as the undercoat agent layer. For example, a siloxane-based organic monomolecular film formed by applying phenethyltrichlorosilane, octadecyltrichlorosilane, hexamethyldisilazane, or the like as a surface treating agent can also be suitably used as an undercoat agent layer.

As the resin component, for example, a resin containing a resin having each constitutional unit constituting the block (b1) or the block (b2), and a resin having a constitutional unit having high affinity for each block constituting the component (BCP) are exemplary examples.

As the resin component for the undercoat agent, for example, it is preferable to use a compound or resin including both a site having high affinity for styrene such as an aromatic ring and a site having high affinity for methyl methacrylate (a highly polar functional group and the like).

As the resin component including both the site having high affinity with styrene and the site having high affinity with methyl methacrylate, for example, for example, a resin obtained by polymerizing at least, as monomers, a monomer having an aromatic ring and a monomer having a highly polar functional group is an exemplary example. As the monomer having an aromatic ring, a monomer having an aryl group obtained by removing a hydrogen atom from an aromatic hydrocarbon ring, such as a phenyl group, a biphenyl group, a fluorenyl group, a naphthyl group, an anthryl group, and a phenanthryl group, or having a heteroaryl group in which carbon atoms constituting the ring of these groups are partially substituted with a heteroatom such as an oxygen atom, a sulfur atom, and a nitrogen atom is an exemplary example. In addition, as the monomer having a highly polar functional group, a monomer having a trimethoxysilyl group, a trichlorosilyl group, an epoxy group, a glycidyl group, a carboxy group, a hydroxy group, a cyano group, a hydroxyalkyl group in which the hydrogen atoms of the alkyl group are partially substituted with a hydroxyl group, and the like is an exemplary example.

In addition, as the compound including both the site having high affinity with styrene and the site having high affinity with methyl methacrylate, a compound including both an aryl group such as phenethyltrichlorosilane and a highly polar functional group, a compound including both an alkyl group such as an alkylsilane compound and a highly polar functional group, and the like are exemplary examples.

As the resin component for the undercoat agent, for example, a resin having both styrene and methyl methacrylate as constitutional units, and a resin having all of styrene, methyl methacrylate, and (hydroxyethyl)methacrylate as constituent units are exemplary examples.

In a case where the resin composition for the undercoat agent has two or more different constitutional units, as the resin, a random copolymer, an alternating polymer of styrene and methyl methacrylate (polymer obtained by alternately copolymerizing each monomer), and the like are exemplary examples.

The undercoat agent can be produced by dissolving the above-described resin component in a solvent.

As such a solvent, any solvent may be used as long as it can dissolve each component to be used and form a homogeneous solution. For example, the same solvent as the organic solvent component exemplary described in the resin composition for forming an etching mask pattern according to the above-described embodiment is an exemplary example.

The type of the support 1 is not particularly limited as long as the resin composition can be applied onto its surface. For example, a substrate made of an inorganic material such as a metal (silicon, copper, chromium, iron, and aluminum), glass, titanium oxide, silica or mica; a substrate made of an oxide such as SiO₂; a substrate made of a nitride such as SiN; a substrate made of an oxynitride such as SiON; and a substrate made of an organic material such as acryl, polystyrene, cellulose, cellulose acetate, phenolic resin, and the like are exemplary examples. Among these, a metal substrate is suitable, and for example, a structure body having a cylinder structure or a lamellar structure vertically oriented is likely to be formed in a silicon substrate (Si substrate) or a copper substrate (Cu substrate). Among these, an Si substrate is particularly suitable.

The size and shape of the support 1 are not particularly limited. The support 1 is not necessarily required to have a smooth surface, and substrates of various shapes can be appropriately selected. For example, a substrate having a curved surface, a flat plate having a surface with an uneven shape, and a substrate with a flaky shape or the like are exemplary examples.

An inorganic and/or organic film may be provided on the surface of the support 1.

As the inorganic film, an inorganic antireflection film (inorganic BARC) is an exemplary example. As the organic film, an organic antireflection film (organic BARC) is an exemplary example.

The inorganic film can be formed, for example, by applying an inorganic antireflection film composition such as a silicon-based material onto a support and by sintering the film.

For example, the organic film can be formed by applying a material for forming an organic film, in which a resin component and the like constituting the film are dissolved in an organic solvent, onto a substrate using a spinner or the like, and baking the film under heating conditions at preferably 200° C. to 300° C. for preferably 30 to 300 seconds and more preferably 60 to 180 seconds. The material for forming an organic film does not necessarily need to have sensitivity to light or electron beams, which is essential for a resist film, and may have sensitivity or does not have to have sensitivity. Specifically, a resist or a resin generally used for the production of semiconductor elements or liquid crystal display elements can be used.

In addition, it is preferable that the material for forming an organic film is a material capable of forming an organic film which can be subjected to etching, particularly dry etching, so that the organic film can be etched by using a pattern formed from a block copolymer, which is formed by processing the BCP layer 3, to transfer the pattern onto the organic film, and an organic film pattern can be formed. Above all, the material for forming an organic film is preferably a material capable of forming an organic film capable of being subjected to etching such as oxygen plasma etching. Such a material for forming an organic film may be a material conventionally used for forming an organic film such as organic BARC. For example, ARC series manufactured by Nissan Chemical Industries, Ltd., AR series manufactured by Rohm and Haas Company, SWK series manufactured by Tokyo Ohka Kogyo Co., Ltd., and the like are exemplary examples.

A method of forming the undercoat agent layer 2 by applying the undercoat agent onto the support 1 is not particularly limited, and the undercoat agent layer 2 can be formed by a known method in the related art.

For example, the undercoat agent layer 2 can be formed by applying the undercoat agent onto the support 1 by a known method in the related art, such as using a spin coating or a spinner, to form a coating film, and drying the coating film.

As a method of drying the coating film, any method of drying the coating film may be used as long as the solvent contained in the undercoat agent can be volatilized, and for example, a method of baking the coating film is an exemplary example. In this case, a baking temperature is preferably 80° C. to 300° C., more preferably 180° C. to 270° C., and still more preferably 220° C. to 270° C. A baking time is preferably 30 to 500 seconds and more preferably 60 to 400 seconds.

A thickness of the undercoat agent layer 2 after drying the coating film is preferably approximately 10 to 100 nm and more preferably approximately 20 to 50 nm.

The surface of the support 1 may be cleaned in advance before forming the undercoat agent layer 2 on the support 1. Coatability of the undercoat agent is improved by cleaning the surface of the support 1.

Regarding the cleaning treatment method, known methods in the related art can be utilized, and an oxygen plasma treatment, an ozone oxidation treatment, an acid alkali treatment, a chemical modification treatment, and the like are exemplary examples.

After the undercoat agent layer 2 is formed, the undercoat agent layer 2 may be rinsed as necessary using a rinse liquid such as a solvent. Since uncrosslinked portions and the like in the undercoat agent layer 2 are removed by this rinsing, the affinity with at least one block constituting the block copolymer is improved, and a phase-separated structure including a cylinder structure or a lamellar structure, oriented in a direction perpendicular to the surface of the support 1, is likely to be formed.

The rinse liquid may be any one which can dissolve the uncrosslinked portions, and a solvent such as propylene glycol monomethyl ether acetate (PGMEA), propylene glycol monomethyl ether (PGME), or ethyl lactate (EL), or a commercially available thinner liquid can be used.

In addition, after the cleaning, post-baking may be performed in order to volatilize the rinse liquid. A temperature condition of the post-baking is preferably 80° C. to 250° C., more preferably 80° C. to 200° C., and still more preferably 80° C. to 150° C. A baking time is preferably 30 to 500 seconds and more preferably 60 to 240 seconds. A thickness of the undercoat agent layer 2 after the post-baking is preferably approximately 1 to 10 nm and more preferably approximately 2 to 7 nm.

Next, the layer 3 (BCP layer) containing the component (BCP) is formed on the undercoat agent layer 2.

The method of forming the BCP layer 3 on the undercoat agent layer 2 is not particularly limited, and a method of applying the resin composition for forming an etching mask pattern according to the above-described embodiment onto the undercoat agent layer 2 by a known method in the related art, such as spin coating or using a spinner, to form a coating film, and drying the coating film is an exemplary example.

A thickness of the BCP layer 3 may be a sufficient thickness for use as an etching mask and for phase separation to occur.

The film thickness of the BCP layer 3 is 25 nm or more. In a case where the film thickness is equal to or more than the above-described lower limit value, the phase-separated structure formed from the BCP layer 3 is likely to remain during etching and is likely to function as a mask.

The film thickness of the BCP layer 3 may be 100 nm or less, 75 nm or less, 50 nm or less, 40 nm or less, or 35 nm or less. In a case where the film thickness is equal to or less than the above-described upper limit value, it is easy to obtain a phase-separated structure having a desired periodic size, and it is easy to improve uniformity of the nanostructure body.

The film thickness of the BCP layer 3 is preferably 25 to 100 nm. For example, in a case where the support 1 is an Si substrate, the thickness of the BCP layer 3 is preferably adjusted to 25 to 100 nm and more preferably 25 to 75 nm.

In the method for manufacturing an etching mask pattern according to the present embodiment described above, by using the above-described resin composition for forming an etching mask pattern, a phase-separated structure having a period (L0) of less than 20 nm and having excellent vertical orientation can be obtained even in a case of being subjected to high-temperature annealing. The film thickness of the phase-separated structure to be obtained is 25 nm or more, and this phase-separated structure can be used for the production of an etching mask pattern.

In addition, according to the method for manufacturing an etching mask pattern according to the present embodiment, it is possible to manufacture a support having a nanostructure body in which position and orientation are more freely designed on the support surface. For example, the formed structure body has high adhesiveness to the support and tends to have a phase-separated structure having a cylinder structure or a lamellar structure, oriented in the direction perpendicular to the surface of the support.

### Optional Step

### Regarding Guide Pattern Forming Step

In the method for manufacturing an etching mask pattern according to the present embodiment, a step of providing a guide pattern on the undercoat agent layer (guide pattern forming step) may be provided before the step (i) and the step (ii) described above. As a result, it is possible to control an array structure of the phase-separated structure.

For example, in a case where the guide pattern is not provided, even for a block copolymer with which a random fingerprint-shaped phase-separated structure is formed, in a case where a groove structure of a resist film is provided on the surface of the undercoat agent layer, a phase-separated structure oriented along the grooves is obtained. According to such a principle, the guide pattern may be provided on the undercoat agent layer 2. In addition, in a case where a surface of the guide pattern has an affinity with any of the blocks constituting the above-described component (BCP), a phase-separated structure oriented in the direction perpendicular to the surface of the support is likely to be formed.

The guide pattern can be formed, for example, using a resist composition.

As the resist composition for forming the guide pattern, among resist compositions and modified products thereof, which are generally used for formation of a resist pattern, any one having the affinity with any of the blocks constituting the above-described component (BCP) can be appropriately selected and used. The resist composition may be any of a positive-type resist composition for forming a positive-tone pattern in which the exposed part of the resist film is dissolved and removed, or a negative-tone resist composition for forming a negative-type pattern in which the unexposed part of the resist film is dissolved and removed; but the resist composition is preferably a negative-type resist composition. As the negative-type resist composition, for example, a resist composition containing an acid generator, and a base material component in which solubility in a liquid developer containing an organic solvent is decreased by the action of an acid, and in which the base material component contains a resin component having a constitutional unit which is decomposed by the action of an acid to have increased polarity, is preferable.

After the resin composition for forming an etching pattern is poured on the undercoat agent layer on which the guide pattern has been formed, an annealing treatment is performed to induce phase separation. Therefore, the resist composition for forming the guide pattern is preferably a composition capable of forming a resist film having excellent solvent resistance and heat resistance.

### Resin Composition for Forming Etching Mask Pattern

As the resin composition for forming an etching mask pattern according to the present embodiment, those described in the embodiment above are exemplary examples. The block copolymer (the component (BCP)) in the resin composition for forming an etching mask pattern can be produced by, for example, a production method including the following steps.

### Method for Producing Block Copolymer (Component (BCP))

Step (p1): step of obtaining a block copolymer having the first block and a precursor of the second block (hereinafter, also referred to as “BCP precursor”)

Step (p2): step of obtaining a block copolymer (component (BCP)) containing the first block and the second block by reacting the precursor of the second block in the BCP precursor with a compound represented by R²—SH (R² is the same as R² in Formula (b2g) described above)

### Step (p1):

The precursor of the second block is composed of a block 2M and a block 2GP. The block 2M is composed of a polymer consisting of a constitutional unit (b2m). The block 2GP is composed of a polymer consisting of a constitutional unit (b2gp) which is a precursor of a constitutional unit (b2g).

The constitutional unit (b2gp) is a constitutional unit including an epoxy group or a vinyl group, and a constitutional unit represented by General Formula (b2gp) is an exemplary example.

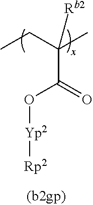

in the formula, Rp² represents an epoxy group or a vinyl group, Yp² represents a linear or branched alkylene group having 1 to 8 carbon atoms, and R^{b2} is a hydrogen atom, an alkyl group having 1 to 5 carbon atoms, or a halogenated alkyl group having 1 to 5 carbon atoms]

The BCP precursor can be obtained, for example, by the following procedure. First, a polymerization reaction of a monomer for inducing the constitutional unit (b1) (for example, styrene or a derivative thereof; hereinafter, also referred to as a monomer (b1)) is performed to synthesize a precursor of the first block.

Next, a monomer for inducing the constitutional unit (b2gp) (for example, glycidyl methacrylate, acrylic methacrylate, or the like; hereinafter, also referred to as a monomer (b2gp)) is added to the obtained polymerization reaction solution to further perform a polymerization reaction.

Next, a monomer for inducing the constitutional unit (b2m) (for example, methyl methacrylate; hereinafter, also referred to as a monomer (b2m)) is added to the obtained polymerization reaction solution to further perform a polymerization reaction, thereby obtaining a BCP precursor.

Alternatively, the polymerization reaction of the monomer (b1) is performed, and then the monomer (b2m) is added to the polymerization reaction solution to perform the polymerization reaction. Next, the monomer (b2gp) is added to the obtained polymerization reaction solution to perform the polymerization reaction, thereby obtaining a BCP precursor.

Alternatively, the polymerization reaction of the monomer (b2m) is performed, and then the monomer (b2gp) is added to the polymerization reaction solution to perform the polymerization reaction. Next, the monomer (b1) is added to the obtained polymerization reaction solution to perform the polymerization reaction, thereby obtaining a BCP precursor.

Alternatively, the polymerization reaction of the monomer (b2gp) is performed, and then the monomer (b2m) is added to the polymerization reaction solution to perform the polymerization reaction. Next, the monomer (b1) is added to the obtained polymerization reaction solution to perform the polymerization reaction, thereby obtaining a BCP precursor.

As the polymerization reaction, living polymerization is preferable because it is easy to synthesize with narrow dispersion. As a preferred living polymerization method, living anionic polymerization and living radical polymerization are exemplary examples, and living anionic polymerization is particularly preferable because the narrow dispersion can be further achieved.

In the step (p1), a proportion the number of moles of the monomer (b1) used in the production of the BCP precursor is preferably 20 to 80 mol %, more preferably 30 to 75 mol %, and still more preferably 35 to 70 mol % with respect to the total number of moles (100 mol %) of the monomer (b1), the monomer (b2gp), and the monomer (b2m).

In the step (p1), a proportion the number of moles of the monomer (b2gp) used in the production of the BCP precursor is preferably 0.5 to 8 mol %, more preferably 1 to 7 mol %, and still more preferably 1.5 to 6 mol % with respect to the total number of moles (100 mol %) of the monomer (b1), the monomer (b2gp), and the monomer (b2m).

In the step (p1), a proportion the number of moles of the monomer (b2m) used in the production of the BCP precursor is preferably 10 to 70 mol %, more preferably 15 to 65 mol %, and still more preferably 20 to 60 mol % with respect to the total number of moles (100 mol %) of the monomer (b1), the monomer (b2gp), and the monomer (b2m).

### Step (p2):

The compound represented by R²—SH (hereinafter, also referred to as “compound (R²—SH)”) is a compound obtained by a reaction of an epoxy group or a vinyl group of the constitutional unit (b2gp) to convert the constitutional unit (b2gp) into the constitutional unit (b2g).

In a case where the constitutional unit (b2gp) includes an epoxy group, the reaction between the BCP precursor and the compound (R²—SH) can be performed in an organic solvent such as tetrahydrofuran in the presence of a catalyst such as lithium hydroxide. As a reaction temperature, for example, 20° C. to 60° C. are exemplary examples, and 30° C. to 50° C. are preferable and 35° C. to 45° C. are more preferable. A reaction time can be appropriately set according to the amount of the BCP precursor used, and may be sufficient to convert all the constitutional units (b2gp) in the precursor of the second block into the constitutional units (b2g). As a reaction time, for example, 1 to 10 hours are exemplary examples. In a case where the constitutional unit (b2gp) includes a vinyl group, the reaction between the BCP precursor and the compound (R²—SH) can be performed by a thiol-ene reaction. The thiol-ene reaction can be carried out in an organic solvent such as tetrahydrofuran in the presence of a catalyst such as azobisisobutyronitrile (AIBN). As a reaction temperature, for example, 60° C. to 90° C. are exemplary examples, and 70° C. to 90° C. are preferable and 75° C. to 85° C. are more preferable. A reaction time can be appropriately set according to the amount of the BCP precursor used, and may be sufficient to convert all the constitutional units (b2gp) in the precursor of the second block into the constitutional units (b2g). As a reaction time, for example, 1 to 10 hours are exemplary examples.

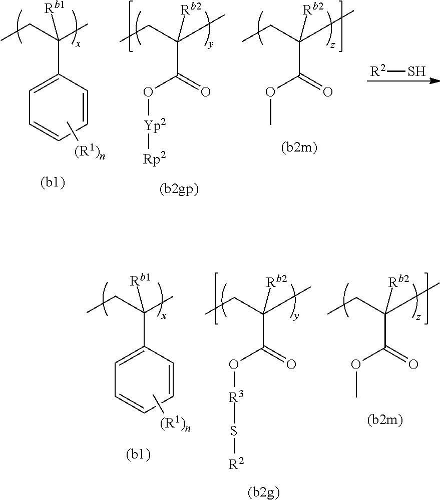

in the formulae, R¹, R^{b1}, and n are the same as R¹, R^{b1}, and n in Formula (b1) described above, R² and R³ are the same as R² and R³ in Formula (b2g) described above, R^{b2}, y, and z are the same as R^{b2}, y, and z in Formula (b2g) and Formula (b2m) described above, Yp² represents a linear or branched alkyl group having 1 to 8 carbon atoms, and Rp² represents an epoxy group or a vinyl group

### Organic Solvent Component

The resin composition for forming an etching mask pattern according to the present embodiment can be prepared by dissolving the above-described component (BCP) in an organic solvent component.

Any organic solvent component may be used as long as it can dissolve each component to be used and form a homogeneous solution, and arbitrary solvents may be selected from any solvents known in the related art as a solvent for a film composition containing a resin as a main component.

As the organic solvent component, for example, lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monoethylether, monopropylether, or monobutylether or monophenylether of any of the polyhydric alcohols or the compounds having an ester bond [among these, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and the like are exemplary examples.

The organic solvent component may be used alone or as a mixed solvent of two or more kinds thereof. Among these, propylene glycol monomethyl ether acetate (PGMEA), propylene glycol monomethyl ether (PGME), cyclohexanone, or EL is preferable.

In addition, a mixed solvent obtained by mixing PGMEA with a polar solvent is also preferable. A blending ratio (mass ratio) of the mixed solvent can be appropriately determined in consideration of compatibility between PGMEA and the polar solvent, and it is preferably in a range of 1:9 to 9:1 and more preferably in a range of 2:8 to 8:2.

For example, in a case where EL is blended as the polar solvent, a mass ratio of PGMEA:EL is preferably 1:9 to 9:1 and more preferably 2:8 to 8:2. In addition, in a case where PGME is blended as the polar solvent, a mass ratio of PGMEA:PGME is preferably 1:9 to 9:1, more preferably 2:8 to 8:2, and still more preferably 3:7 to 7:3. In addition, in a case where PGME and cyclohexanone are blended as the polar solvent, a mass ratio of PGMEA:(PGME+cyclohexanone) is preferably 1:9 to 9:1, more preferably 2:8 to 8:2, and still more preferably 3:7 to 7:3.

In addition, as the organic solvent component in the resin composition for forming an etching mask pattern, in addition to those solvents, a mixed solvent in which PGMEA, EL, or the above-described mixed solvent of PGMEA and a polar solvent is mixed with γ-butyrolactone is also preferable. In this case, as a mixing proportion, a mass ratio of the former and the latter is preferably set to 70:30 to 95:5.

The concentration of the organic solvent component contained in the resin composition for forming an etching mask pattern is not particularly limited, and the component is appropriately set at a concentration with which the coating can be performed according to the coating film thickness. A concentration of solid contents is generally used in a range of 0.2% to 70% by mass, preferably in a range of 0.2% to 50% by mass.

### Optional Component

In addition to the above-described component (BCP) and organic solvent component, the resin composition for forming an etching mask pattern may further contain, as desired, a miscible additive such as an additional resin for improving the performance of the layer, a surfactant for improving coatability, a dissolution inhibitor, a plasticizer, a stabilizer, a colorant, a halation inhibitor, a dye, a sensitizer, a base promoter, and a basic compound.

With the resin composition for forming an etching mask pattern according to the present embodiment described above, it is possible to form a phase-separated structure having a period (L0) of less than 20 nm and having excellent vertical orientation even in a case of being subjected to high-temperature annealing. Therefore, the phase-separated structure can be used as an etching mask.

In a case where the second block has the constitutional unit (b2g), the component (BCP) can increase the value of χ as compared with a block copolymer (PS-b-PMMA) having a block of styrene and a block of methyl methacrylate. As a result, it is possible to form a finer phase-separated structure having a shorter period by using the block copolymer having a lower degree of polymerization (N). However, in a case where the value of χ is high, the vertical orientation tends to decrease. In particular, at a film thickness (for example, a film thickness of 25 nm or more, and preferably 30 nm or more) applicable to the etching mask pattern, the component (BCP) is less likely to form a phase-separated structure vertically oriented.

In the resin composition for forming an etching mask pattern according to the present embodiment, since the second block consists of the block 2M and the block 2G and y/(y+z) is 0.01 or more and 0.11 or less, the vertical orientation is improved, it is possible to form a phase-separated structure which is vertically oriented at a film thickness applicable to the etching mask pattern.

### Example

Hereinafter, the present invention will be described in more detail with reference to examples, but the present invention is not limited to these examples.

### Synthesis of BCP Precursor

BCP precursors (1) to (8) were synthesized by the following procedures.

### Synthesis of BCP Precursor (1)

All anionic polymerizations were carried out in an argon atmosphere. 30 mL of tetrahydrofuran (THF) and lithium chloride (LiCl) (21.2 mg, 0.500 mmol) were transferred into a 50 mL Schlenk tube and cooled to −78° C. in a Coolnics bath. Sec-butyllithium (Sec-BuLi) (1.05M hexane/cyclohexane solution) was added to the Schlenk tube until the color of the solution turned yellow. The Schlenk tube was removed from the Coolnics bath and warmed to room temperature until the colorless solution was obtained. The Schlenk tube was cooled again in a Coolnics bath to −78° C., and sec-BuLi (0.095 mL, 0.100 mmol) was added as an initiator. Styrene (1.19 mL, 10.4 mmol) was added thereto, and the mixture was stirred for 30 minutes. As a result, a bright orange colored solution was obtained. 1,1-diphenylethylene (DPE) (0.088 mL, 0.50 mmol) was added thereof, and the color of the solution turned deep red. After stirring for 30 minutes, glycidyl methacrylate (GMA) (0.157 mL, 1.31 mmol) was added thereto, and the mixture was stirred for 120 minutes. The color of the solution turned from red to transparent. Thereafter, methyl methacrylate (MMA) (1.41 mL, 13.3 mmol) was added thereto, and the mixture was stirred for 30 minutes. As a terminator, 3 mL of degassed methanol (MeOH) was added to the Schlenk tube to terminate the polymerization. The Schlenk tube was pulled up from the Coolnics bath, and the solution was introduced into MeOH to perform reprecipitation. The solid of the precipitate was filtered and then dried under reduced pressure at 40° C. to obtain a white powder of a BCP precursor (1) (2.57 g, 86% yield).

### Synthesis of BCP Precursor (2)

A BCP precursor (2) was synthesized in the same manner as in the synthesis of the BCP precursor (1) described above, except that the use amount of St was changed to 1.07 mL (9.29 mmol), the use amount of GMA was changed to 0.117 mL (0.976 mmol), and the use amount of MMA was changed to 0.936 mL (8.78 mmol).

### Synthesis of BCP Precursor (3)

A BCP precursor (3) was synthesized in the same manner as in the synthesis of the BCP precursor (1) described above, except that the use amount of St was changed to 1.27 mL (11.0 mmol), the use amount of GMA was changed to 0.0988 mL (0.828 mmol), and the use amount of MMA was changed to 0.891 mL (8.37 mmol).

### Synthesis of BCP Precursor (4)

A BCP precursor (4) was synthesized in the same manner as in the synthesis of the BCP precursor (1) described above, except that the use amount of St was changed to 1.63 mL (14.1 mmol), the use amount of GMA was changed to 0.0475 mL (0.398 mmol), and the use amount of MMA was changed to 0.664 mL (6.23 mmol).

### Synthesis of BCP Precursor (5)

A BCP precursor (5) was synthesized in the same manner as in the synthesis of the BCP precursor (1) described above, except that the use amount of St was changed to 1.20 mL (10.4 mmol), the use amount of GMA was changed to 0.257 mL (2.15 mmol), and the use amount of MMA was changed to 0.916 mL (8.60 mmol).

### Synthesis of BCP Precursor (6)

A BCP precursor (6) was synthesized in the same manner as in the synthesis of the BCP precursor (1) described above, except that the use amount of St was changed to 1.83 mL (15.9 mmol), the use amount of GMA was changed to 0.108 mL (0.905 mmol), and the use amount of MMA was changed to 0.645 mL (6.06 mmol).

### Synthesis of BCP Precursor (7)

A BCP precursor (7) was synthesized in the same manner as in the synthesis of the BCP precursor (1) described above, except that the use amount of St was changed to 1.72 mL (15.0 mmol), the use amount of GMA was changed to 0.105 mL (0.882 mmol), and the use amount of MMA was changed to 0.760 mL (7.13 mmol).

### Synthesis of BCP Precursor (8)

A BCP precursor (8) was synthesized in the same manner as in the synthesis of the BCP precursor (1) described above, except that the use amount of St was changed to 1.38 mL (12.0 mmol), the use amount of GMA was changed to 0 mL (0 mmol), and the use amount of MMA was changed to 1.33 mL (12.5 mmol).

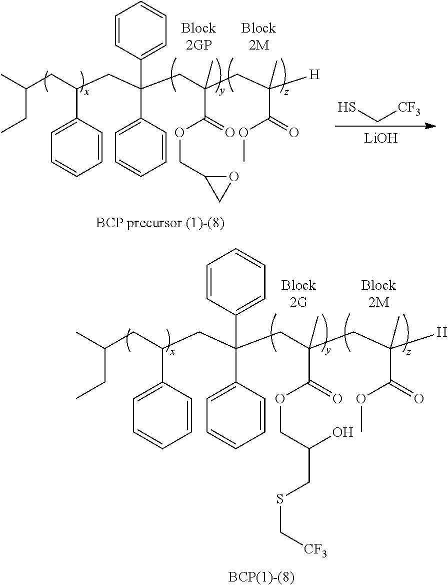

BCP precursors (9) to (15) were synthesized by the following procedures.

### Synthesis of BCP Precursor (9)

All anionic polymerizations were carried out in an argon atmosphere. 30 mL of tetrahydrofuran (THF) and lithium chloride (LiCl) (21.2 mg, 0.500 mmol) were transferred into a 50 mL Schlenk tube and cooled to −78° C. in a Coolnics bath. Sec-butyllithium (Sec-BuLi) (1.05M hexane/cyclohexane solution) was added to the Schlenk tube until the color of the solution turned yellow. The Schlenk tube was removed from the Coolnics bath and warmed to room temperature until the colorless solution was obtained. The Schlenk tube was cooled again in a Coolnics bath to −78° C., and sec-BuLi (0.095 mL, 0.100 mmol) was added as an initiator. Styrene (1.36 mL, 11.8 mmol) was added thereto, and the mixture was stirred for 30 minutes. As a result, a bright orange colored solution was obtained. 1,1-diphenylethylene (DPE) (0.088 mL, 0.50 mmol) was added thereof, and the color of the solution turned deep red. After stirring for 30 minutes, methyl methacrylate (MMA) (1.29 mL, 12.1 mmol) was added thereto, and the mixture was stirred for 30 minutes. The color of the solution turned from red to transparent. Thereafter, glycidyl methacrylate (GMA) (0.143 mL, 1.20 mmol) was added thereto, and the mixture was stirred for 120 minutes. As a terminator, 3 mL of degassed methanol (MeOH) was added to the Schlenk tube to terminate the polymerization. The Schlenk tube was pulled up from the Coolnics bath, and the solution was introduced into MeOH to perform reprecipitation. The solid of the precipitate was filtered and then dried under reduced pressure at 40° C. to obtain a white powder of a BCP precursor (9) (2.54 g, 84% yield).

### Synthesis of BCP Precursor (10)

A BCP precursor (10) was synthesized in the same manner as in the synthesis of the BCP precursor (9) described above, except that the use amount of St was changed to 1.11 mL (9.70 mmol), the use amount of MMA was changed to 0.901 mL (8.46 mmol), and the use amount of GMA was changed to 0.112 mL (0.940 mmol).

### Synthesis of BCP Precursor (11)

A BCP precursor (11) was synthesized in the same manner as in the synthesis of the BCP precursor (9) described above, except that the use amount of St was changed to 1.27 mL (11.1 mmol), the use amount of MMA was changed to 0.933 mL (8.76 mmol), and the use amount of GMA was changed to 0.0787 mL (0.659 mmol).

### Synthesis of BCP Precursor (12)

A BCP precursor (12) was synthesized in the same manner as in the synthesis of the BCP precursor (9) described above, except that the use amount of St was changed to 1.65 mL (14.4 mmol), the use amount of MMA was changed to 0.643 mL (6.04 mmol), and the use amount of GMA was changed to 0.0460 mL (0.385 mmol).

### Synthesis of BCP Precursor (13)

A BCP precursor (13) was synthesized in the same manner as in the synthesis of the BCP precursor (9) described above, except that the use amount of St was changed to 1.28 mL (11.1 mmol), the use amount of MMA was changed to 0.888 mL (8.34 mmol), and the use amount of GMA was changed to 0.234 mL (1.96 mmol).

### Synthesis of BCP Precursor (14)

A BCP precursor (14) was synthesized in the same manner as in the synthesis of the BCP precursor (9) described above, except that the use amount of St was changed to 1.89 mL (16.4 mmol), the use amount of MMA was changed to 0.591 mL (5.55 mmol), and the use amount of GMA was changed to 0.108 mL (0.903 mmol).

### Synthesis of BCP Precursor (15)

A BCP precursor (15) was synthesized in the same manner as in the synthesis of the BCP precursor (9) described above, except that the use amount of St was changed to 1.94 mL (16.9 mmol), the use amount of MMA was changed to 0.600 mL (5.63 mmol), and the use amount of GMA was changed to 0.0831 mL (0.696 mmol).

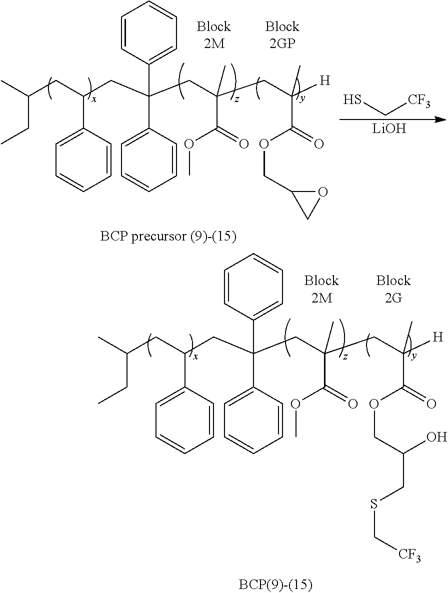

A BCP precursor (16) was synthesized by the following procedure.

### Synthesis of BCP Precursor (16)

All anionic polymerizations were carried out in an argon atmosphere. 30 mL of tetrahydrofuran (THF) and lithium chloride (LiCl) (21.2 mg, 0.500 mmol) were transferred into a 50 mL Schlenk tube and cooled to −78° C. in a Coolnics bath. Sec-butyllithium (Sec-BuLi) (1.05M hexane/cyclohexane solution) was added to the Schlenk tube until the color of the solution turned yellow. The Schlenk tube was removed from the Coolnics bath and warmed to room temperature until the colorless solution was obtained. The Schlenk tube was cooled again in a Coolnics bath to −78° C., and sec-BuLi (0.095 mL, 0.100 mmol) was added as an initiator. Styrene (1.03 mL, 9.04 mmol) was added thereto, and the mixture was stirred for 30 minutes. As a result, a bright orange colored solution was obtained. 1,1-diphenylethylene (DPE) (0.088 mL, 0.50 mmol) was added thereof, and the color of the solution turned deep red. After stirring for 30 minutes, a monomer mixture of methyl methacrylate (MMA) (1.11 mL, 10.5 mmol) and glycidyl methacrylate (GMA) (0.139 mL, 1.16 mmol) was added thereto, and the mixture was stirred for 30 minutes. The color of the solution turned from red to transparent. As a terminator, 3 mL of degassed methanol (MeOH) was added to the Schlenk tube to terminate the polymerization. The Schlenk tube was pulled up from the Coolnics bath, and the solution was introduced into MeOH to perform reprecipitation. The solid of the precipitate was filtered and then dried under reduced pressure at 40° C. to obtain a white powder of a BCP precursor (16) (2.41 g, 88% yield).

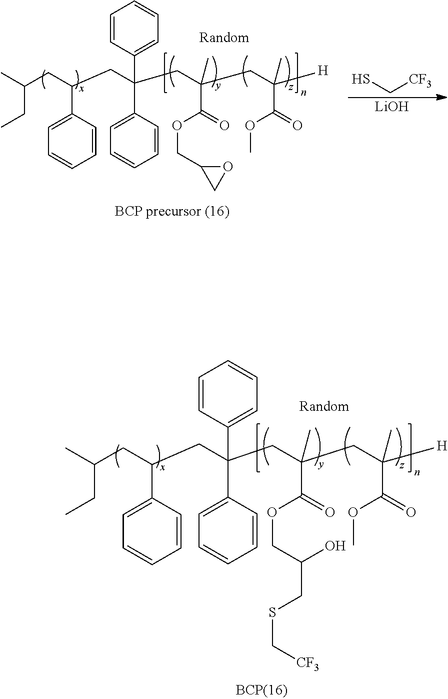

In the BCP precursors (1) to (15), the precursor of the second block consists of the block 2M composed of a polymer consisting of a repeating structure of a constitutional unit derived from methyl methacrylate, and the block 2G composed of a polymer consisting of a repeating structure of a constitutional unit derived from glycidyl methacrylate.

In the BCP precursor (16), the precursor of the second block is a random copolymer consisting of a structure in which the constitutional unit derived from methyl methacrylate and the constitutional unit derived from glycidyl methacrylate are arranged in a disordered manner.

### Synthesis of Block Copolymer

### Synthesis of BCP (1)

### Synthesis of Block Copolymer: BCP (1)

0.2 g of the BCP precursor (1) and THF (20 wt % solution) were placed into a 10 mL glass tube, and the mixture was immersed in an ice water tank. A 1 wt % lithium hydroxide (LiOH) aqueous solution (LiOH 0.05 molar equivalent/GMA unit) and 2,2,2-trifluoroethanethiol (2 molar equivalent/GMA unit) were added to the glass tube. After stirring the mixture at room temperature for 20 minutes, a reactor was set to 40° C., and the mixture was stirred for 3 hours to synthesize BCP (1). Residual reagents were removed by repeatedly performing precipitation with methanol or water/methanol several times, depending on the Mn and PHFMA fractions of the synthesized BCP (1). The product was dried under reduced pressure overnight at room temperature to obtain a white powder of the BCP (1). Mn of the BCP (1) was measured by size-exclusion chromatography (SEC).

The NMR analysis value of BCP (1) was as follows.

¹H NMR (400 MHz, Acetone-d6, δ, ppm): 0.84 (s, α-CH3, PMMA), 0.87 (s, α-CH3, PMMA), 1.00 (s, α-CH3, PMMA), 1.03 (s, α-CH3, PHFMA), 1.23 to 1.73 (br, backbone, —CH2-CH—, PS), 1.75 to 2.23 (br, backbone, —CH2-CH—, PS; br, backbone, —CH2-C(CH3)-, PHFMA and PMMA), 2.78 to 3.00 (d, CH(OH)—CH2-S—, PHFMA), 3.40 to 3.77 (s, —S—CH2-CF3, PHFMA), 3.54 to 3.75 (s, —OCH3, PMMA), 3.92 to 4.07 (d, —(C═O)O—CH2-, PHFMA), 4.07 to 4.18 (m, —CH(OH)—, PHFMA) 4.50 to 4.72 (br, —CH(OH)—, PHFMA), 6.36 to 6.84 (m, o-aromatic, PS), 6.85 to 7.35 (m, m- and p-aromatic, PS)

### Synthesis of BCP (2) to (16)

BCP (2) to (16) were each synthesized in the same manner as in the synthesis of BCP (1), except that the BCP precursors (2) to (16) were each used in place of the BCP precursor (1).

Mn of BCP (1) to (16) was measured by size-exclusion chromatography (SEC).

The number-average molecular weight (Mn) of each block copolymer synthesized above, the values of x, y, and z in the reaction formula, and the value of y/(y+z) in the above reaction formula are listed in Table 1. x, y, and z are mol % in the obtained BCP (1) to (16). The value of y/(y+z) is a value obtained by rounding off the fourth decimal place or less.

TABLE 1

| | Mn | x | y | z | y/y + z |
|---|---|---|---|---|---|
| BCP (1) | 27500 | 42 | 5 | 53 | 0.086 |
| BCP (2) | 26800 | 49 | 5 | 46 | 0.098 |
| BCP (3) | 26900 | 55 | 4 | 41 | 0.088 |
| BCP (4) | 26500 | 68 | 2 | 30 | 0.062 |
| BCP (5) | 27200 | 49 | 10 | 41 | 0.196 |
| BCP (6) | 26500 | 69 | 4 | 27 | 0.129 |
| BCP (7) | 26900 | 65 | 4 | 31 | 0.114 |
| BCP (8) | 27100 | 49 | 0 | 51 | 0.000 |

TABLE 2

| | Mn | x | y | z | y/y + z |
|---|---|---|---|---|---|
| BCP (9) | 27100 | 47 | 5 | 48 | 0.094 |
| BCP (10) | 27200 | 51 | 5 | 44 | 0.102 |
| BCP (11) | 27500 | 54 | 3 | 43 | 0.065 |
| BCP (12) | 26700 | 69 | 2 | 29 | 0.064 |
| BCP (13) | 26600 | 52 | 9 | 39 | 0.187 |
| BCP (14) | 27000 | 72 | 4 | 24 | 0.142 |
| BCP (15) | 26900 | 73 | 3 | 24 | 0.111 |
| BCP (16) | 27300 | 49 | 5 | 46 | 0.098 |

Each component shown in Tables 1 and 2 was mixed and dissolved in the organic solvent component to prepare a resin composition for forming an etching mask pattern (solid content concentration: 1% by mass) of each example.

TABLE 3

| | Block copolymer | Organic solvent component |
|---|---|---|
| Example 1 | BCP-1 | (S)-1 |
| | [100] | [9900] |
| Example 2 | BCP-2 | (S)-1 |
| | [100] | [9900] |
| Example 3 | BCP-3 | (S)-1 |
| | [100] | [9900] |
| Example 4 | BCP-4 | (S)-1 |
| | [100] | [9900] |
| Comparative | BCP-5 | (S)-1 |
| Example 1 | [100] | [9900] |
| Comparative | BCP-6 | (S)-1 |
| Example 2 | [100] | [9900] |
| Comparative | BCP-7 | (S)-1 |
| Example 3 | [100] | [9900] |
| Comparative | BCP-8 | (S)-1 |
| Example 4 | [100] | [9900] |

TABLE 4

| | Block | Organic |
|---|---|---|
| | copolymer | solvent component |
| Example 5 | BCP-9 | (S)-1 |
| | [100] | [9900] |
| Example 6 | BCP-10 | (S)-1 |
| | [100] | [9900] |
| Example 7 | BCP-11 | (S)-1 |
| | [100] | [9900] |
| Example 8 | BCP-12 | (S)-1 |
| | [100] | [9900] |
| Comparative | BCP-13 | (S)-1 |
| Example 5 | [100] | [9900] |
| Comparative | BCP-14 | (S)-1 |
| Example 6 | [100] | [9900] |
| Comparative | BCP-15 | (S)-1 |
| Example 7 | [100] | [9900] |
| Reference | BCP-16 | (S)-1 |
| Example 1 | [100] | [9900] |

In Tables 3 and 4, each abbreviation has the following meaning. A numerical value in the brackets is a blending amount (part by mass).
BCP-1: BCP (1) described above
BCP-2: BCP (2) described above
BCP-3: BCP (3) described above
BCP-4: BCP (4) described above
BCP-5: BCP (5) described above
BCP-6: BCP (6) described above
BCP-7: BCP (7) described above
BCP-8: BCP (8) described above
BCP-9: BCP (9) described above
BCP-10: BCP (10) described above
BCP-11: BCP (11) described above
BCP-12: BCP (12) described above
BCP-13: BCP (13) described above
BCP-14: BCP (14) described above
BCP-15: BCP (15) described above
BCP-16: BCP (16) described above

### (S)-1: Propylene Glycol Monomethyl Ether Acetate (PGMEA)

Using the resin composition for forming an etching mask pattern of each of Examples, a structure body including a phase-separated structure was obtained by a production method including the following step (i) and step (ii).

### Evaluation 1

### Production of Structure Body Including Phase-Separated Structure

### Preparation of Undercoat Agent

In order to prepare an undercoat agent, a resin NL-(1) for an undercoat agent was prepared. The NL-(1) is a random copolymer consisting of styrene, methyl methacrylate, and (hydroxyethyl)methacrylate.

A compositional ratio (proportion (molar ratio) of constitutional units in the structural formula) of the NL-(1) (styrene/methyl methacrylate/(hydroxyethyl)methacrylate) was 49/46/5, and the number-average molecular weight (Mn) thereof was 28,000.

The resin NL-(1) for an undercoat agent was mixed with PGMEA and dissolved to prepare an undercoat agent NL-1.

### Step (i):

A 12-inch silicon wafer was prepared as a support.

The undercoat agent NL-1 was spin-coated on a silicon substrate, and then heated in an air atmosphere at 250° C. for 5 minutes. An undercoat agent layer having a film thickness of 30 nm and formed of the resin NL-(1) for an undercoat agent was formed on a surface of the substrate.

Next, the undercoat agent layer was rinsed using a rinsing solution consisting of propylene glycol monomethyl ether (PGME) and propylene glycol monomethyl ether acetate (PGMEA) (PGME/PGMEA=7/3). Next, the undercoat agent layer was heated at 100° C. for 1 minute to volatilize the rinsing solution.

Next, the resin composition of each of Examples was spin-coated on the substrate such that the film thickness was 25 nm, thereby forming a resin composition layer (layer containing a block copolymer).

### Step (ii):

The resin composition layer formed on the above-described substrate was pre-baked at 90° C. for 60 seconds in a nitrogen atmosphere, and then annealed at 290° C. for 5 minutes in a nitrogen atmosphere to form a phase-separated structure.

### Evaluation of Resolution

With regard to the phase-separated structure on the surface of the obtained substrate, an SEM image was acquired at a magnification of 100,000 times using “CG6300” of Hitachi High-Tech Corporation. Next, analysis of the pattern period was performed from the SEM image using “Terminal PC software” of Hitachi High-Technologies Corporation. The resolution was evaluated based on the following evaluation standard. The results of the evaluation are shown in Tables 5 and 6 as “Resolution”.

### Determination Standard:

A: period was less than 20 nm.

B: period was 20 nm or more.

In a case where the resin compositions of Comparative Examples 1 to 7 were used, since the phase-separated structure was not formed, the period could not be calculated. These are described as

### Evaluation of Vertical Orientation

The surface (in the phase-separated state) of the obtained substrate was observed with a length-measuring SEM (scanning electron microscope, trade name: CG6300, manufactured by Hitachi High-Tech Corporation). As a result of such observation, vertical orientation was evaluated based on the following evaluation standard. The results are shown in Tables 5 and 6 as “Vertical orientation”.

### Determination Standard:

A: vertically oriented phase-separated structure was formed on the entire surface of the substrate.

B: vertically oriented phase-separated structure was not formed in a part of the substrate.

C: vertically oriented phase-separated structure was not formed on the entire surface of the substrate.

TABLE 5

| | Resolution | Vertical orientation |
|---|---|---|
| Example 1 | A | A |
| Example 2 | A | A |
| Example 3 | A | A |
| Example 4 | A | A |
| Comparative | — | C |
| Example 1 | | |
| Comparative | — | C |
| Example 2 | | |
| Comparative | — | C |
| Example 3 | | |
| Comparative | — | C |
| Example 4 | | |

TABLE 6

| | | Vertical |
|---|---|---|
| | Resolution | orientation |
| Example 5 | A | A |
| Example 6 | A | A |
| Example 7 | A | A |
| Example 8 | A | A |
| Comparative | — | C |
| Example 5 | | |
| Comparative | — | C |
| Example 6 | | |
| Comparative | — | C |
| Example 7 | | |
| Reference | A | B |
| Example 1 | | |

In Examples 1 to 8 in which y/(y+z) in the second block was 0.01 or more and 0.11 or less, the phase-separated structure vertically oriented was formed on the entire surface of the substrate, and the resolution was less than 20 nm.

In Comparative Examples 1 to 8 in which y/(y+z) in the second block was less than 0.01 or more than 0.11, the phase-separated structure vertically oriented was not formed on the entire surface of the substrate, and the resolution could not be measured.

In Reference Example 1 in which the second block was a random copolymer, the resolution was less than 20 nm, but the phase-separated structure vertically oriented was not formed at a part of the substrate.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A method for manufacturing an etching mask pattern, comprising:
applying a resin composition for forming an etching mask pattern onto a support to form a layer containing a block copolymer and having a film thickness of 25 nm or more; and
phase-separating the layer containing the block copolymer,
wherein the resin composition for forming an etching mask pattern contains a block copolymer having a first block and a second block,
the first block comprises a polymer consisting of a repeating structure of a constitutional unit represented by General Formula (b1), and
the second block consists of a block 2M which comprises a polymer consisting of a repeating structure of a constitutional unit represented by General Formula (b2m) and a block 2G which comprises a polymer consisting of a repeating structure of a constitutional unit represented by General Formula (b2g), 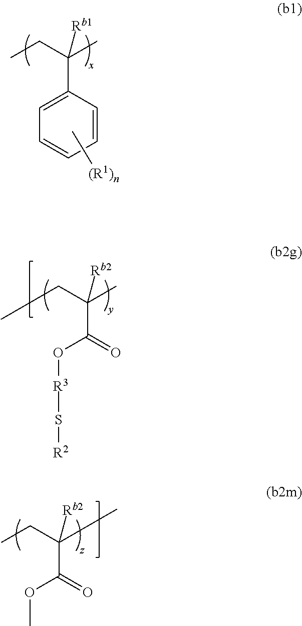
wherein in Formula (b1), R¹ is an alkyl group which may have an oxygen atom or a silicon atom, n is an integer of 0 to 5, and R^{b1} is a hydrogen atom or a methyl group,
in Formula (b2g), R² is an alkyl group which may have a silicon atom, a fluorine atom, a carboxy group, an amino group, a cyano group, a hydroxy group, or a phosphoric acid group, and R³ is a linear alkylene group having 1 to 10 carbon atoms or a branched alkylene group having 2 to 10 carbon atoms, each of which may have a hydroxy group,
and in Formulae (b2g) and (b2m), R^{b2}'s are each independently a hydrogen atom, an alkyl group having 1 to 5 carbon atoms, or a halogenated alkyl group having 1 to 5 carbon atoms, x, y, and z represent a molar ratio, x+y+z is 100 mol %, y/(y+z) is 0.01 or more and 0.11 or less, and x is 20 to 80 mol %.

2. The method for manufacturing an etching mask pattern according to claim 1, wherein the block copolymer is a polymer represented by General Formula (BCP1) or General Formula (BCP2): 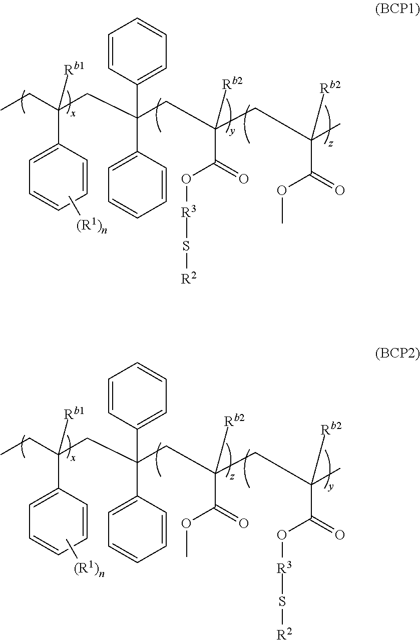
Wherein in Formulae (BCP1) and (BCP2), R¹ is an alkyl group which may have an oxygen atom or a silicon atom, n is an integer of 0 to 5, and R^{b1} is a hydrogen atom or a methyl group,
in Formulae (BCP1) and (BCP2), R² is an alkyl group which may have a silicon atom, a fluorine atom, a carboxy group, an amino group, a cyano group, a hydroxy group, or a phosphoric acid group, and R³ is a linear alkylene group having 1 to 10 carbon atoms or a branched alkylene group having 2 to 10 carbon atoms, each of which may have a hydroxy group, and
in Formulae (BCP1) and (BCP2), R^{b2} is a hydrogen atom, an alkyl group having 1 to 5 carbon atoms, or a halogenated alkyl group having 1 to 5 carbon atoms, x, y, and z represent a molar ratio, x+y+z is 100 mol %, y/(y+z) is 0.01 or more and 0.11 or less, and x is 20 to 80 mol %.

3. The method for manufacturing an etching mask pattern according to claim 1, wherein a number-average molecular weight of the block copolymer is 15,000 to 35,000.

4. A resin composition for forming an etching mask pattern, comprising a block copolymer having a first block and a second block,
wherein the first block comprises a polymer consisting of a repeating structure of a constitutional unit represented by General Formula (b1), and
the second block consists of a block 2M which comprises a polymer consisting of a repeating structure of a constitutional unit represented by General Formula (b2m) and a block 2G which comprises a polymer consisting of a repeating structure of a constitutional unit represented by General Formula (b2g), 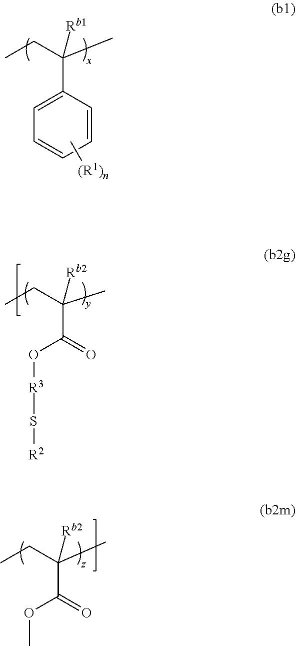
wherein in Formula (b1), R¹ is an alkyl group which may have an oxygen atom or a silicon atom, n is an integer of 0 to 5, and R^{b1} is a hydrogen atom or a methyl group,
in Formula (b2g), R² is an alkyl group which may have a silicon atom, a fluorine atom, a carboxy group, an amino group, a cyano group, a hydroxy group, or a phosphoric acid group, and R³ is a linear alkylene group having 1 to 10 carbon atoms or a branched alkylene group having 2 to 10 carbon atoms, each of which may have a hydroxy group, and
in Formulae (b2g) and (b2m), R^{b2}'s are each independently a hydrogen atom, an alkyl group having 1 to 5 carbon atoms, or a halogenated alkyl group having 1 to 5 carbon atoms, x, y, and z represent a molar ratio, x+y+z is 100 mol %, y/(y+z) is 0.01 or more and 0.11 or less, and x is 20 to 80 mol %.

5. The resin composition for forming an etching mask pattern according to claim 4, wherein the block copolymer is a polymer represented by General Formula (BCP1) or General Formula (BCP2): 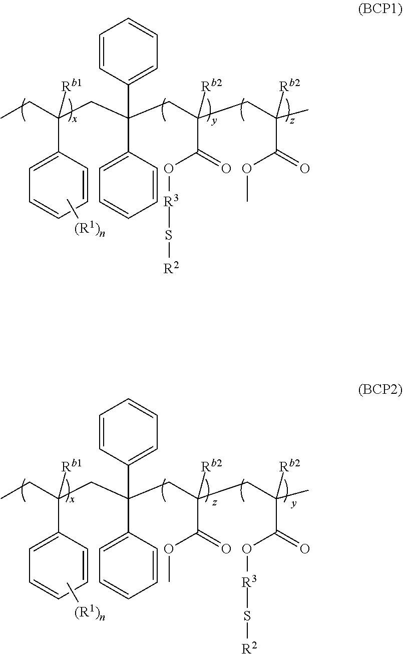
Wherein in Formulae (BCP1) and (BCP2), R¹ is an alkyl group which may have an oxygen atom or a silicon atom, n is an integer of 0 to 5, and R^{b1} is a hydrogen atom or a methyl group,
in Formulae (BCP1) and (BCP2), R² is an alkyl group which may have a silicon atom, a fluorine atom, a carboxy group, an amino group, a cyano group, a hydroxy group, or a phosphoric acid group, and R³ is a linear alkylene group having 1 to 10 carbon atoms or a branched alkylene group having 2 to 10 carbon atoms, each of which may have a hydroxy group,
and in Formulae (BCP1) and (BCP2), R^{b2} is a hydrogen atom, an alkyl group having 1 to 5 carbon atoms, or a halogenated alkyl group having 1 to 5 carbon atoms, x, y, and z represent a molar ratio, x+y+z is 100 mol %, y/(y+z) is 0.01 or more and 0.11 or less, and x is 20 to 80 mol %.

6. The resin composition for forming an etching mask pattern according to claim 4, wherein a number-average molecular weight of the block copolymer is 15,000 to 35,000.
